(19) United States
(12) Patent Application Publication
(10) Pub. No.: US 2025/0210072 A1
(43) Pub. Date: Jun. 26, 2025

(54) BITLINE SENSING AMPLIFIER AND MEMORY DEVICE INCLUDING THE SAME

(71) Applicant: Samsung Electronics Co., Ltd., Suwon-si (KR)

(72) Inventors: MIJI JANG, Suwon-si (KR); YOUNGHUN SEO, Suwon-si (KR)

(21) Appl. No.: 18/883,399

(22) Filed: Sep. 12, 2024

(30) Foreign Application Priority Data
Dec. 21, 2023 (KR) 10-2023-0188526

(51) Int. Cl. G11C 7/06; G11C 7/10; G11C 7/12; G11C 11/22

(52) U.S. Cl. CPC G11C 7/06; G11C 7/1051; G11C 7/12; G11C 11/223; G11C 11/2273

(57) ABSTRACT

Disclosed is a BLSA that reads data of a memory cell and includes an amplifying circuit amplifying a difference between a first voltage level of the second node and a second voltage level of the first node. The amplifying circuit includes a first PMOS transistor connected between the second node and a third node and operating in response to the second voltage level, a second PMOS transistor connected between the first node and the third node and operating in response to the first voltage level, a first NMOS transistor connected between the second node and a fourth node connected to a first bitline of a first memory cell and operating in response to the first voltage level, and a second NMOS transistor connected between the second node and a fifth node connected to a second bitline of a second memory cell and operating in response to the second voltage level.

### CROSS-REFERENCE TO RELATED APPLICATIONS

This application claims priority under 35 U.S.C. § 119 to Korean Patent Application No. 10-2023-0188526 filed on Dec. 21, 2023, in the Korean Intellectual Property Office, the disclosures of which are incorporated by reference herein in their entireties.

### BACKGROUND

Embodiments of the present disclosure described herein relate to a semiconductor memory device, and more particularly, relate to a bitline sensing amplifier and a memory device including the same.

Various memory devices are required for various electronic devices or semiconductor devices to operate. Memory devices which are mainly used include dynamic random access memory (DRAM) or static RAM (SRAM). Memory devices are used in a variety of fields, and as semiconductor devices become faster, memory devices are being developed to provide data to coincide with the increase in speed.

### SUMMARY

Embodiments of the present disclosure provide a bitline sensing amplifier for determining data of memory cells by comparing magnitudes of currents of bitlines and amplifying a comparison result and a memory device including the same.

According to an embodiment, a bitline sensing amplifier configured to read data of a memory cell includes an equalization circuit that is connected to a first node and a second node and provides an equalization voltage to the first node and the second node, and an amplifying circuit that amplifies a difference between a first voltage level of the second node and a second voltage level of the first node. The amplifying circuit includes a first p-type metal-oxide-semiconductor (PMOS) transistor that is connected between the second node and a third node and operates in response to the second voltage level, a second PMOS transistor that is connected between the first node and the third node and operates in response to the first voltage level, a first n-type metal-oxide-semiconductor (NMOS) transistor that is connected between the second node and a fourth node connected to a first bitline of a first memory cell and operates in response to the first voltage level, and a second NMOS transistor that is connected between the second node and a fifth node connected to a second bitline of a second memory cell and operates in response to the second voltage level.

According to an embodiment, a bitline sensing amplifier configured to read data of a memory cell includes an equalization circuit that is connected to a first node and a second node and provides an equalization voltage to the first node and the second node, a first amplifying circuit that amplifies a difference between a first voltage level of the second node and a second voltage level of the first node, and a second amplifying circuit that disconnects the bitline sensing amplifier from a first bitline connected to a first memory cell and a second bitline connected to a second memory cell. The first amplifying circuit includes a first NMOS transistor that is connected between the first node and a third node and operates in response to the first voltage level, and a second NMOS transistor that is connected between the second node and a fourth node and operates in response to the second voltage level. The second amplifying circuit includes a third NMOS transistor that is connected between a fifth node connected to the third node and the first bitline and operates in response to a first control signal, and a fourth NMOS transistor that is connected between a sixth node connected to the fourth node and the second bitline and operates in response to the first control signal.

According to an embodiment, a memory device configured to store data includes a memory cell array that stores the data and includes a first memory cell, a second memory cell, and a bitline sensing amplifier, and an input/output circuit that inputs or receives the data to or from the memory cell array. The bitline sensing amplifier includes an equalization circuit that is connected to a first node and a second node and provides an equalization voltage to the first node and the second node, and an amplifying circuit that amplifies a difference between a first voltage level of the second node and a second voltage level of the first node. The amplifying circuit includes a first NMOS transistor that is connected between the first node and a third node connected to a first bitline of the first memory cell and operates in response to the first voltage level, and a second NMOS transistor that is connected between the second node and a fourth node connected to a second bitline of the second memory cell and operates in response to the second voltage level.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a memory device according to an embodiment of the present disclosure.

FIG. 2 is a block diagram illustrating a bitline sensing amplifier and memory cells of FIG. 1, according to an embodiment of the present disclosure.

FIG. 3 is a circuit diagram illustrating a bitline sensing amplifier of FIG. 2 in detail, according to an embodiment of the present disclosure.

FIG. 4A is a circuit diagram illustrating a second read/write circuit of FIG. 3 in detail, according to an embodiment of the present disclosure.

FIG. 4B is a circuit diagram illustrating a second read/write circuit of FIG. 3 in detail, according to an embodiment of the present disclosure.

FIG. 5A is a circuit diagram illustrating an equalization circuit of FIG. 3 in detail, according to an embodiment of the present disclosure.

FIG. 5B is a circuit diagram illustrating an equalization circuit of FIG. 3 in detail, according to an embodiment of the present disclosure.

FIG. 6 is a timing diagram illustrating how signals and voltage levels change over time during a read operation of a bitline sensing amplifier of FIGS. 2 to 5, according to an embodiment of the present disclosure.

FIG. 7 is a flowchart illustrating a data read operation sequence of a bitline sensing amplifier of FIG. 3, according to an embodiment of the present disclosure.

FIG. 8 is a circuit diagram illustrating a bitline sensing amplifier of FIG. 2 in detail, according to an embodiment of the present disclosure.

FIG. 9 is a circuit diagram illustrating a bitline sensing amplifier of FIG. 2, according to an embodiment of the present disclosure.

FIG. 10 is a timing diagram illustrating how signals and voltages change over time during a read operation of a bitline sensing amplifier of FIG. 9, according to an embodiment of the present disclosure.

FIG. 11 is a circuit diagram illustrating a bitline sensing amplifier of FIG. 2 in detail, according to an embodiment of the present disclosure.

FIG. 12 is a block diagram illustrating an electronic system according to an embodiment of the present disclosure.

### DETAILED DESCRIPTION

Below, embodiments of the present disclosure will be described in detail and clearly to such an extent that an ordinary one in the art easily carries out the present disclosure. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” to another element, the connection being referred to is an electrical connection. An electrical connection is one in which an electrical signal can be transferred from one component to another (although such electrical signal may be attenuated in strength as it is transferred and may be selectively transferred). Moreover, components that are “directly connected” share a common electrical node through electrical connections by one or more conductors, such as, for example, wires, pads, internal electrical lines, through vias, etc. As such, directly electrically connected components do not include components electrically connected through active elements, such as transistors or diodes.

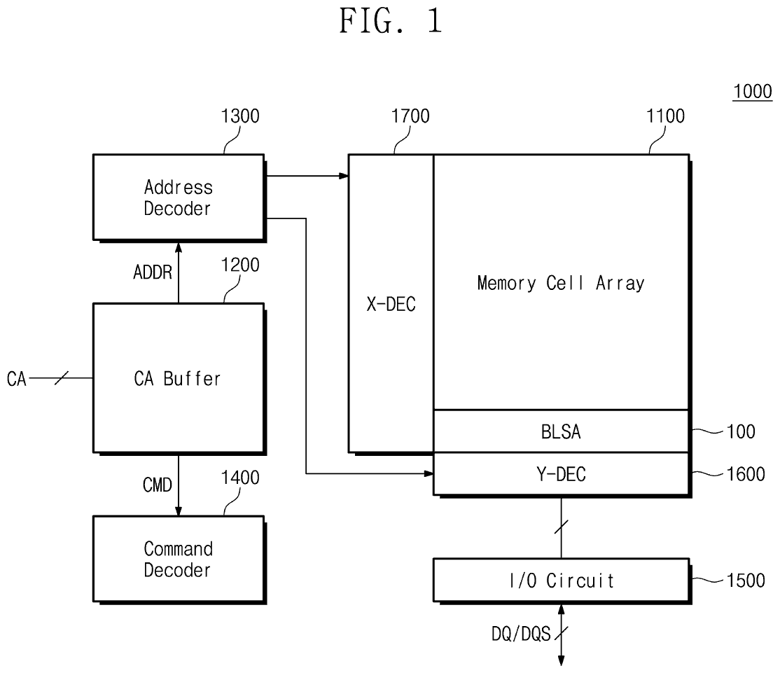

FIG. 1 is a block diagram illustrating a memory device according to an embodiment of the present disclosure. As various devices such as a magnetic random access memory (MRAM), a ferroelectric random access memory (FeRAM), and a ferroelectric field effect transistor (FeFET) are developed, breaking away from the structure of existing memory devices, there is a need to sense a current flowing to a bitline connected to a memory cell. Accordingly, unlike an amplifier which senses voltages and amplifies a difference between the sensed voltages, a bitline sensing amplifier senses currents and amplifies a difference between the sensed currents is used to read these unconventional memory devices.

Referring to FIG. 1, a memory device 1000 may include a memory cell array 1100, a command/address (CA) buffer 1200, an address decoder 1300, a command decoder 1400, an input/output circuit 1500. The memory cell array 1100 may include a bitline sensing amplifier 100. The memory device 1000 according to an embodiment of the present disclosure will be described in detail with reference to FIG. 1.

The memory cell array 1100 may include a plurality of memory cells. The plurality of memory cells may be connected to wordlines and bitlines. In an embodiment, each of the plurality of memory cells may be a ferro-electric field-effect-transistor (FeFET) cell, but the present disclosure is not limited thereto. For example, each of the plurality of memory cells may be implemented with one of various types of memory cells such as a phase RAM (PRAM), a magnetic RAM (MRAM), a resistive RAM (RRAM), and a thyristor RAM (TRAM).

The memory cell array 1100 may be connected to a column decoder (Y-decoder 1600) through the plurality of bitlines and may be connected to a row decoder (X-decoder 1700) through the plurality of wordlines. The Y-decoder 1600 may control the plurality of bitlines under control of the address decoder 1300. The X-decoder 1700 may control the plurality of wordlines under control of the address decoder 1300.

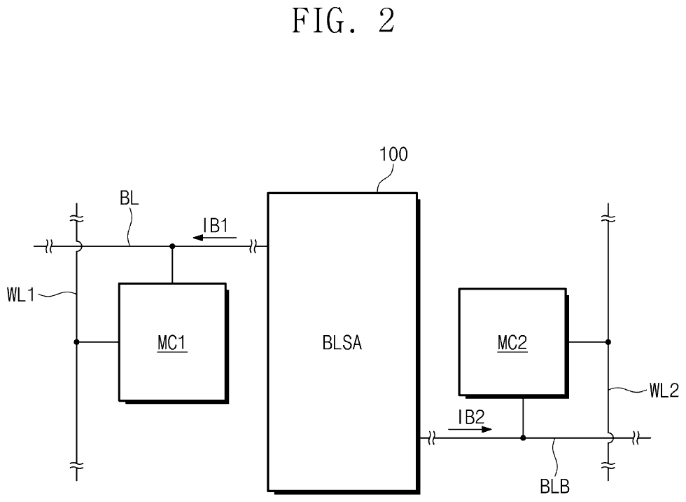

The bitline sensing amplifier 100 may be included in the memory cell array 1100. The bitline sensing amplifier 100 may read data from respective memory cells or may write data in respective memory cells. The bitline sensing amplifier 100 may be connected to bitlines of the memory cells. The bitline sensing amplifier 100 according to embodiments of the present disclosure will be described in detail with reference to FIGS. 2 to 11.

The command/address (CA) buffer 1200 may be configured to receive a command/address from an external device (e.g., a memory controller or a register clock driver RCD)) through command/address lines CA and to temporarily store or buffer signals input thereto.

The address decoder 1300 may be configured to receive an address signal ADDR from the command/address (CA) buffer 1200 and to decode the received address signal ADDR. The address decoder 1300 may be configured to control the Y-decoder 1600 and the X-decoder 1700 based on the decoding result.

The command decoder 1400 may receive a command signal CMD from the command/address (CA) buffer 1200 and may decode the received command signal CMD. The command decoder 1400 may control the components of the memory device 1000 based on the decoding result. For example, when the command signal CMD received from the command/address (CA) buffer 1200 corresponds to a write command, the command decoder 1400 may control an operation of the input/output circuit 1500 such that data received through data lines DQ are written in the memory cell array 1100. Alternatively, when the command signal CMD received from the command/address (CA) buffer 1200 is a read command, the command decoder 1400 may control an operation of the input/output circuit 1500 such that data stored in the memory cell array 1100 are read out.

Through the data lines DQ/DQS, the input/output circuit 1500 may be configured to receive data from an external device (e.g., a memory controller) or to transmit data to the external device. Under control of the command decoder 1400, the input/output circuit 1500 may read data from the memory cell array 1100 or may write data in the memory cell array 1100.

FIG. 2 is a block diagram illustrating the bitline sensing amplifier 100 according to an embodiment of the present disclosure. Referring to FIG. 2, the bitline sensing amplifier 100, a first memory cell MC1, and a second memory cell MC2 are illustrated. The first memory cell MC1 may be connected to a first wordline WL1 and a first bitline BL, and the second memory cell MC2 may be connected to a second wordline WL2 and a second bitline BLB.

The bitline sensing amplifier 100 may be connected to two bitlines. For example, the bitline sensing amplifier 100 may be connected to the first bitline BL connected to the first memory cell MC1 and the second bitline BLB connected to the second memory cell MC2. In an embodiment, the bitline sensing amplifier 100 may sense and amplify voltage levels or current levels of the first bitline BL and the second bitline BLB. For example, the bitline sensing amplifier 100 may sense and amplify a level of a current flowing to each of the first bitline BL and the second bitline BLB.

Below, a first current IB1 may refer to a current flowing into the first memory cell MC1 (or a current flowing through the first bitline BL) in response to the condition that the first wordline WL1 is activated (e.g., that a turn-on voltage of a memory cell is applied to the first wordline WL1). Likewise, a second current IB2 may refer to a current flowing into the second memory cell MC2 (or a current flowing through the second bitline BLB) in response to the condition that the second wordline WL2 is activated (e.g., that the turn-on voltage of the memory cell is applied to the second wordline WL2).

The bitline sensing amplifier 100 may compare voltage levels or current levels and may amplify a difference between the voltage levels or the current levels. In an embodiment, the bitline sensing amplifier 100 may amplify a difference between the current levels of the first bitline BL and the second BLB. For example, the bitline sensing amplifier 100 may amplify the difference between the first current IB1 flowing to the first bitline BL and the second current IB2 flowing to the second bitline BLB. An example in which two bitlines are connected to the bitline sensing amplifier 100 is illustrated in FIG. 2, but the present disclosure is not limited thereto. For example, according to some embodiments, pairs of bitlines may be additionally connected to each of a plurality of memory cells. The bitline sensing amplifier 100 according to an embodiment of the present disclosure will be described with reference to the following drawings.

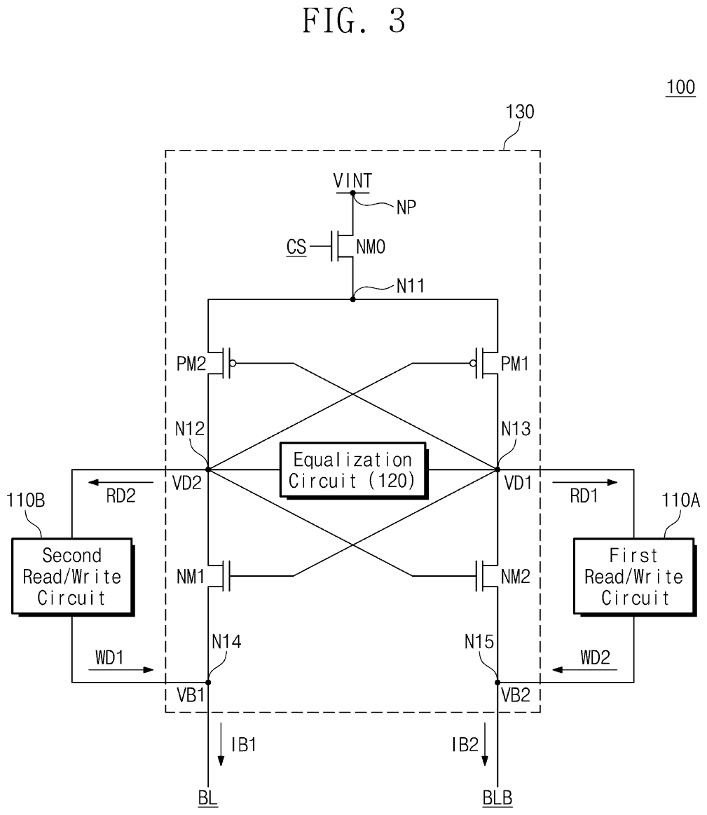

FIG. 3 is a circuit diagram illustrating the bitline sensing amplifier 100 of FIG. 2 in detail, according to an embodiment of the present disclosure. Referring to FIG. 3, the bitline sensing amplifier 100 may include a first read/write circuit 110A, a second read/write circuit 110B, an equalization circuit 120, and an amplifying circuit 130. The bitline sensing amplifier 100 of FIG. 3 may be connected to the first memory cell MC1 of FIG. 2 through the first bitline BL and may be connected to the second memory cell MC2 of FIG. 2 through the second bitline BLB. The bitline sensing amplifier 100 according to an embodiment of the present disclosure will be described in detail with reference to FIG. 3.

The first read/write circuit 110A or the second read/write circuit 110B may transfer data stored in the memory cells MC1 and MC2 to the input/output circuit 1500 of FIG. 1 or may transfer data to be written in the memory cells MC1 and MC2 to the memory cells MC1 and MC2. In an embodiment, the first read/write circuit 110A or the second read/write circuit 110B may transfer data to be written to the memory cells MC1 and MC2 in the form of a voltage level. In an embodiment, the first read/write circuit 110A or the second read/write circuit 110B may transfer data of the memory cells MC1 and MC2 to the input/output circuit 1500 in the form of a voltage level.

Below, for convenience of description, first write data WD1 may be data to be written in the first memory cell MC1, and first read data RD1 may be data read from the first memory cell MC1. Likewise, second write data WD2 may be data to be written in the second memory cell MC2, and second read data RD2 may be data read from the second memory cell MC2.

The first read/write circuit 110A may be connected to opposite ends of a second NMOS transistor NM2 (e.g., the source and drain of the transistor which may together be referred to as opposite ends of a transistor). In the following description, the phrase “transistor connected between” two elements indicates that a first element of the two elements is connected to one of the source/drain of the transistor and a second element of the two elements is connected to the other of the source/drain of the transistor. For example, a first end and a second end, which may be referred to together as opposite ends, of the first read/write circuit 110A may be respectively connected to a third node N13 and a fifth node N15. In an embodiment, the first read/write circuit 110A may be provided with the first read data RD1 from the first memory cell MC1. For example, the first read/write circuit 110A may be provided with the first read data RD1 from the first memory cell MC1, based on a first data voltage level VD1 of the third node N13. In an embodiment, the first read/write circuit 110A may provide the second write data WD2 to the second memory cell MC2. For example, the first read/write circuit 110A may provide the second write data WD2 to the second memory cell MC2, based on a second bitline voltage level VB2 of the fifth node N15.

The second read/write circuit 110B may be connected to opposite ends of a first NMOS transistor NM1. For example, opposite ends of the second read/write circuit 110B may be respectively connected to a second node N12 and a fourth node N14. In an embodiment, the second read/write circuit 110B may be provided with the second read data RD2 from the second memory cell MC2. For example, the second read/write circuit 110B may be provided with the second read data RD2 from the second memory cell MC2, based on a second data voltage level VD2 of the second node N12. In an embodiment, the second read/write circuit 110B may provide the first write data WD1 to the first memory cell MC1. For example, the second read/write circuit 110B may provide the first write data WD1 to the first memory cell MC1, based on a first bitline voltage level VB1 of the fourth node N14.

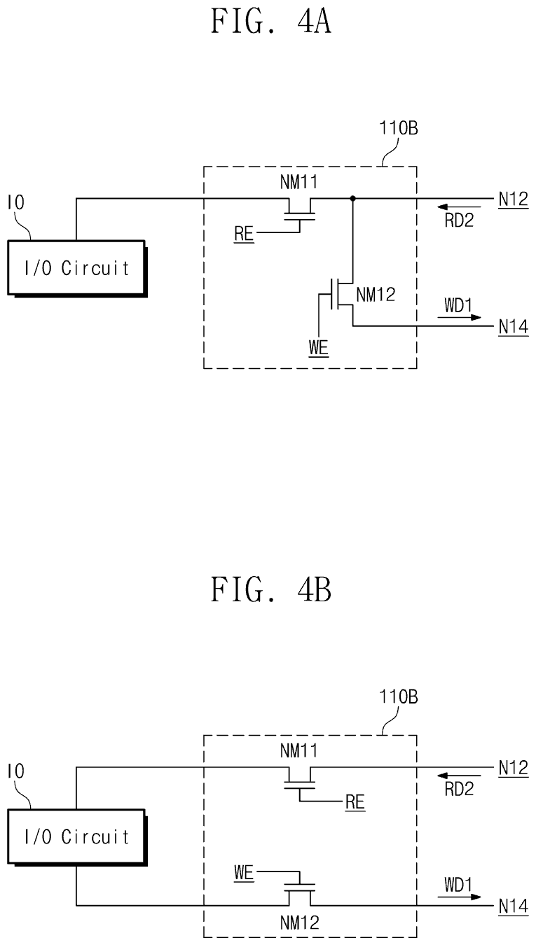

Examples of a read/write circuit, such as the first read/write circuit 110A and/or the second read/write circuit 110B, will be described in detail with reference to FIGS. 4A and 4B. Below, the description will be given based on an embodiment in which the memory device 1000 of FIG. 1 reads data of the first memory cell MC1 of FIG. 2 or writes data thereto. This is provided as an example, and the present disclosure is not limited thereto. The description is given based on the case where the first read/write circuit 110A or the second read/write circuit 110B senses data based on the voltage level of the second node N12 or the third node N13, but the present disclosure is not limited thereto. For example, according to some embodiments, data may be exchanged based on a level of a current flowing to the second node N12 or the third node N13.

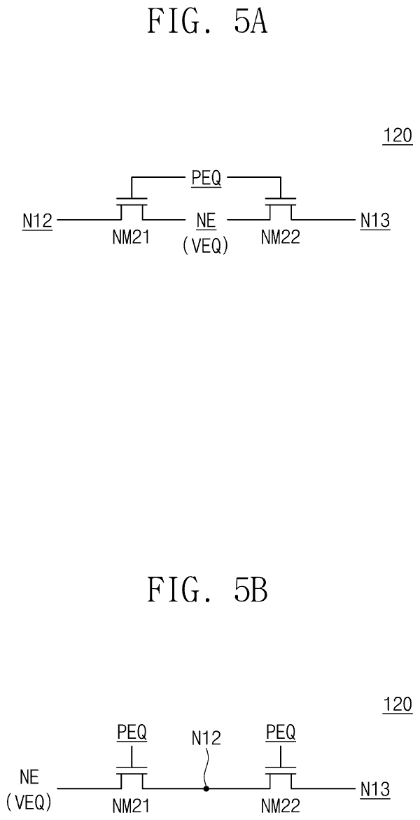

The equalization circuit 120 may equalize voltages of the second node N12 and the third node N13 of the amplifying circuit 130. The bitline sensing amplifier 100 may perform a data read operation, based on an operation of the equalization circuit 120. A structure of the equalization circuit 120 will be described in detail with reference to FIGS. 5A and 5B.

The amplifying circuit 130 may sense and amplify current levels of bitlines. Referring to FIG. 3, the amplifying circuit 130 may include a 0-th n-type metal-oxide-semiconductor field effect transistor (NMOS transistor) NM0, the first NMOS transistor NM1, the second NMOS transistor NM2, a first p-type metal-oxide-semiconductor field effect transistor (PMOS transistor) PM1, and a second PMOS transistor PM2.

In an embodiment, the amplifying circuit 130 may sense the first current IB1 and the second current IB2. For example, the amplifying circuit 130 may sense the first current IB1 through the fourth node N14 and may sense the second current IB2 through the third node N13. In an embodiment, the amplifying circuit 130 may amplify a difference between the first current IB1 and the second current IB2, and the bitline sensing amplifier 100 may sense data stored in the memory cells MC1 and MC2, based on the amplification of the amplifying circuit 130.

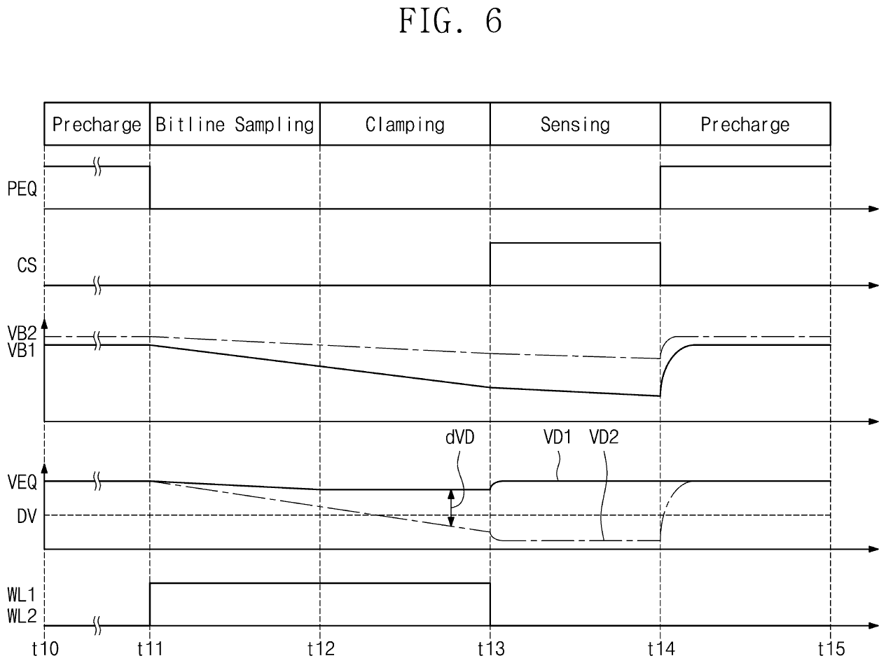

Referring to FIG. 3, the 0-th NMOS transistor NM0 may be connected between a power node NP and a first node N11 and may operate in response to a control signal CS (e.g., a control signal CS may be transmitted to the gate of the 0-th NMOS transistor NM0). In the following description, a transistor may be said to “operating” when a current passes through the transistor between the source and drain. An NMOS transistor may operate responsive to a positive voltage differential between the source/drain and the gate exceeding a threshold, while a PMOS transistor may operate responsive to a negative voltage differential between the gate and the source/drain exceeding a threshold. When a signal is applied to a transistor, a voltage of the signal may be applied to the gate of the transistor to operate the transistor. The control signal CS will be described in detail with reference to FIG. 6. In an embodiment, a voltage applied to the power node NP may be an internal voltage VINT which is provided to memory cells such as by a power source. When the 0-th NMOS transistor NM0 is turned on (e.g., control signal activates the 0-th NMOS transistor NM0), the 0-th NMOS transistor NM0 may provide power to the first node N11 (e.g., an electrical path between the power node NP and the first node N11 is formed), and thus, the amplification operation of the amplifying circuit 130 may be performed.

The first PMOS transistor PM1 may be connected between the first node N11 and the third node N13, and a gate node of the first PMOS transistor PM1 may be connected to the second node N12. The first PMOS transistor PM1 may operate in response to the second data voltage level VD2. Likewise, the second PMOS transistor PM2 may be connected between the first node N11 and the second node N12, and a gate node of the second PMOS transistor PM2 may be connected to the third node N13. The second PMOS transistor PM2 may operate in response to the first data voltage level VD1.

The first NMOS transistor NM1 may be connected between the second node N12 and the fourth node N14, and a gate node of the first NMOS transistor NM1 may be connected to the third node N13. That is, the first NMOS transistor NM1 may operate in response to the first data voltage level VD1. The second NMOS transistor NM2 may be connected between the third node N13 and the fifth node N15, and a gate node of the second NMOS transistor NM2 may be connected to the second node N12. That is, the second NMOS transistor NM2 may operate in response to the second data voltage level VD2. In an embodiment, the first NMOS transistor NM1 or the second NMOS transistor NM2 may clamp the first data voltage level VD1 or the second data voltage level VD2 before the power is supplied through the 0-th NMOS transistor NM0. An operation of the amplifying circuit 130 will be described in detail with reference to FIG. 6 together.

The bitline sensing amplifier described with reference to FIG. 3 and a structure of a bitline sensing amplifier to be described later is described based on the case where the bitline sensing amplifier is connected to two memory cells MC1 and MC2, but the present disclosure is not limited thereto. For example, according to some embodiments, a plurality of memory cells may be connected to the first bitline BL and the second bitline BLB. Also, the description is given based on the case where the bitline sensing amplifier 100 senses a pair of bitlines BL and BLB disposed on opposite sides thereof, but the present disclosure is not limited thereto. For example, according to some embodiments, a plurality of bitline sensing amplifiers whose structure (refer to FIG. 3) is the same as that of the bitline sensing amplifier 100 of FIG. 2 may be provided for each of a plurality of bitlines.

FIGS. 4A and 4B are circuit diagrams illustrating the second read/write circuit 110B of FIG. 3 in detail, according to an embodiment of the present disclosure. FIGS. 4A and 4B may be collectively referred to as “FIG. 4”. A circuit according to an embodiment of the present disclosure, which writes data in the memory cells MC1 and MC2 of FIG. 2 or reads data from the memory cells MC1 and MC2, will be described in detail with reference to FIG. 4. FIG. 4 shows the second read/write circuit 110B and is described based on the second read/write circuit 110B. However, it should be understood that the first read/write circuit 110A is also implemented in the same structure as the second read/write circuit 110B (e.g., the first read/write circuit 110A and the second read/write circuit 110B may have the same structure).

In an embodiment, the input/output circuit IO may correspond to the input/output circuit 1500 of FIG. 1. In another embodiment, the input/output circuit IO may be located between the input/output circuit 1500 of FIG. 1 and the bitline sensing amplifier 100 to transfer the read data to the input/output circuit 1500 of FIG. 1 or to transfer the write data provided from the input/output circuit 1500 of FIG. 1 to each node (e.g., the fourth node N14 or the fifth node N15).

Referring to FIGS. 3 and 4A, in some embodiments, the second read/write circuit 110B may include a first NMOS transistor NM11 and a second NMOS transistor NM12. The first NMOS transistor NM11 may be connected between the second node N12 and the input/output circuit IO and may operate in response to a read enable signal RE. The second NMOS transistor NM12 may be connected between the second node N12 and the fourth node N14 and may operate in response to a write enable signal WE.

The first NMOS transistor NM11 may provide the second read data RD2 from the second node N12 to the input/output circuit IO in response to the read enable signal RE. The second NMOS transistor NM12 may provide the first write data WD1 to the fourth node N14 in response to the write enable signal WE. In this case, the first NMOS transistor NM11 may be turned on such that the second node N12 and the input/output circuit IO are connected.

Like the second read/write circuit 110B, the first read/write circuit 110A may include a first NMOS transistor and a second NMOS transistor. The first NMOS transistor of the first read/write circuit 110A may operate in response to the read enable signal RE and may be connected between an input/output circuit and the third node N13. The second NMOS transistor of the first read/write circuit 110A may be connected between the third node N13 and the fifth node N15 and may operate in response to the write enable signal WE.

Referring to FIGS. 3 and 4B, like the embodiments described in reference to FIG. 4A, in some embodiments the second read/write circuit 110B may include the first NMOS transistor NM11 and the second NMOS transistor NM12. The first NMOS transistor NM11 may be connected between the second node N12 and the input/output circuit IO and may operate in response to the read enable signal RE. The second NMOS transistor NM12 may be connected between the fourth node N14 and the input/output circuit IO and may operate in response to the write enable signal WE. The input/output circuit IO may correspond to the input/output circuit 1500 of FIG. 1 or may be an input/output circuit between the input/output circuit 1500 of FIG. 1 and the bitline sensing amplifier 100.

The first NMOS transistor NM11 may provide the second read data RD2 from the second node N12 to the input/output circuit IO in response to the read enable signal RE. The second NMOS transistor NM12 may provide the first write data WD1 from the input/output circuit IO to the fourth node N14 in response to the write enable signal WE.

Like the second read/write circuit 110B, the first read/write circuit 110A may include a first NMOS transistor and a second NMOS transistor. The first NMOS transistor of the first read/write circuit 110A may operate in response to the read enable signal RE and may be connected between an input/output circuit and the third node N13. The second NMOS transistor of the first read/write circuit 110A may be connected between the fifth node N15 and the input/output circuit and may operate in response to the write enable signal WE.

FIGS. 5A and 5B are circuit diagrams illustrating the equalization circuit 120 FIG. 3, according to an embodiment of the present disclosure. FIGS. 5A and 5B may be collectively referred to as “FIG. 5”. Referring to FIG. 5, the equalization circuit 120 may include a first NMOS transistor NM21 and a second NMOS transistor NM22. The equalization circuit 120 according to an embodiment of the present disclosure will be described in detail with reference to FIG. 5.

Referring to FIGS. 3 and 5A together, the first NMOS transistor NM21 may be connected between an equalization node NE and the second node N12 and may operate in response to an equalization signal PEQ. The second NMOS transistor NM22 may be connected between the equalization node NE and the third node N13 and may operate in response to the equalization signal PEQ.

In an embodiment, a voltage of the equalization node NE may be an equalization voltage VEQ. The second data voltage level VD2 of the second node N12 and the first data voltage level VD1 of the third node N13 may be equalized based on the operation of the equalization circuit 120 of FIG. 5A. For example, the first data voltage level VD1 and the second data voltage level VD2 may be equalized with the equalization voltage VEQ based on the operation of the equalization circuit 120.

Referring to FIGS. 3 and 5B, the first NMOS transistor NM21 may be connected between the equalization node NE and the second node N12 and may operate in response to the equalization signal PEQ. The second NMOS transistor NM22 may be connected between the second node N12 and the third node N13 and may operate in response to the equalization signal PEQ.

In an embodiment, a voltage of the equalization node NE may be the equalization voltage VEQ. The second data voltage level VD2 of the second node N12 and the first data voltage level VD1 of the third node N13 may be equalized with the equalization voltage VEQ based on the operation of the equalization circuit 120 of FIG. 5B. FIG. 5B is described based on an embodiment in which the first NMOS transistor NM21 is connected to the second node N12, but the present disclosure is not limited thereto. For example, according to some embodiments, the first NMOS transistor NM21 may be connected between the third node N13 and the equalization node NE.

Below, for convenience of description, the read operation or the write operation will be described based on the first memory cell MC1 of FIG. 2. The second memory cell MC2 may be a reference cell, and the reference cell may refer to a cell for determining data stored in memory cells. In an embodiment, a current flowing to the second memory cell MC2 which is turned on by a wordline may be to a reference current for determining data 1 or data 0 (e.g., a low bit or high bit in a memory cell). “LOW” may indicate a value (e.g., a voltage level) of a signal which is used to turn off a transistor or a memory cell operating in response to a signal, and “HIGH” may indicate a value (e.g., a voltage level) of a signal which is used to turn on a transistor or a memory cell operating in response to a signal. In an embodiment, a magnitude of a current flowing into (or through) a memory cell when data 1 is stored in the memory cell may be greater than a magnitude of a current flowing into (or through) a memory cell when data 0 is stored in the memory cell. Below, the description will be given based on an embodiment where the magnitude of the current flowing into (or through) the memory cell when data 1 is stored in the memory cell is greater than the magnitude of the current flowing into (or through) the memory cell when data 0 is stored in the memory cell, but the present disclosure is not limited thereto.

FIG. 6 is a timing diagram illustrating respective voltages and signals changing when a bitline sensing amplifier as described in relation to FIGS. 2 through 5 operates, according to an embodiment of the present disclosure. An operation of the bitline sensing amplifier 100 according to an embodiment of the present disclosure will be described in detail with reference to FIGS. 2 to 6. FIG. 6 will be described based on the case where data 1 is stored in the first memory cell MC1, but the present disclosure is not limited thereto. For example, according to some embodiments, data 0 may be stored in the first memory cell MC1 or the first memory cell MC1 may be the reference cell and the read operation or write operation on the second memory cell MC2 may be performed. In FIG. 6, because the data read operation on the first memory cell MC1 is performed by the bitline sensing amplifier 100, the write enable signal WE may maintain LOW throughout the whole operation. In an embodiment, the read enable signal RE may have HIGH during the whole operation or during a sensing period.

Referring to FIGS. 3 and 6, a time period from t10, which is a start time point, to t11 may be a precharge period. Before the first time point t11, based on the precharge operation of the bitline sensing amplifier 100, the first data voltage level VD1 and the second data voltage level VD2 may reach the equalization voltage VEQ. The operation of the bitline sensing amplifier 100 in the precharge period will be described in detail in a time period from a fourth time point t14 to a fifth time point t15. In FIG. 6, signals before wave patterns of the respective signals are provided as an example, but the present disclosure is not limited thereto. For example, it should be understood that that the signals are illustrated to show states or voltage levels of the respective signals at the time of reaching the first time point t11.

A time period from t11 to t12 may be a bitline sampling period. Referring to FIG. 2, together, during the bitline sampling period, the wordlines WL1 and WL2 may be at HIGH. When the wordlines WL1 and WL2 are at HIGH, currents, that is, the first current IB1 and the second current IB2 may start to flow within the memory cells MC1 and MC2.

The bitline sensing amplifier 100 may sense the first current IB1 and the second current IB2 through the two bitlines BL and BLB and the NMOS transistors NM1 and NM2. The first data voltage level VD1 may decrease in response to the first current IB1, and the second data voltage level VD2 may decrease in response to the second current IB2 (i.e., the current flows in a state where a separate external power is not applied to NMOS transistors so the charge is depleted as the current flows therefrom).

Because data 1 is present in the first memory cell MC1, the magnitude of the first current IB1 may be greater than the magnitude of the second current IB2. Accordingly, a rate at which the second data voltage level VD2 is decreased by the first current IB1 may be faster than a rate at which the first data voltage level VD1 is decreased by the second current IB2. In the bitline sampling period, the equalization signal PEQ may be at LOW, and the control signal CS may also be at LOW.

In an embodiment, at the second time point t12, which is an end point of the bitline sampling period, the second NMOS transistor NM2 may be turned off. Because the wordline is activated and the first current IB1 flows through the first NMOS transistor NM1, the second data voltage level VD2 may decrease. The second NMOS transistor NM2 may be turned off when a voltage between the fifth node N15 and the second node N12 is less than a threshold value of the second NMOS transistor NM2. Therefore, at the second time point t12, the second NMOS transistor NM2 is turned off and the first data voltage level VD1 may be clamped (e.g., held to a near constant value).

A time period from t12 to t13 may be a clamping period. The first data voltage level VD1 may maintain the voltage level at the second time point t12 during the whole clamping period. The second data voltage level VD2 may continuously decrease during the whole clamping period. Because the first data voltage level VD1 is clamped, the first NMOS transistor NM1 maintains a turn-on state, and thus, the first current IB1 flows through the first NMOS transistor NM1.

With the first data voltage level VD1 clamped and the second data voltage level VD2 continuing to decrease, a voltage difference dVD of the voltage levels of the first data voltage level VD1 and the second data voltage level VD2 may gradually increase. In the clamping period, the wordlines WL1 and WL2 may maintain HIGH, and the equalization signal PEQ and the control signal CS may maintain LOW like the bitline sampling period.

A time period from t13 to t14 may be a sensing period. At the third time point t13, the amplifying circuit 130 may start the amplification operation. The equalization signal PEQ may maintain LOW, the control signal CS may transition to HIGH, and the wordlines WL1 and WL2 may be set to LOW.

In an embodiment, the 0-th NMOS transistor NM0 may be turned on at the third time point t13. For example, the 0-th NMOS transistor NM0 may be turned on in response to the control signal CS transitioning to HIGH at the third time point t13. As the 0-th NMOS transistor NM0 is turned on, the 0-th NMOS transistor NM0 may supply power to the amplifying circuit 130. For example, as the 0-th NMOS transistor NM0 is turned on, a power supply voltage level may be provided to the first node N11, and the amplifying circuit 130 may be provided with the power in response thereto.

As the power is supplied to the amplifying circuit 130, the amplifying circuit 130 may start to amplify the voltage difference dVD between the voltage levels of the first data voltage level VD1 and the second data voltage level VD2. In detail, the first PMOS transistor PM1 and the second PMOS transistor PM2 may be turned on in response to that the internal voltage VINT is applied to the first node N11 (e.g., the voltage differential between the gate of the first PMOS transistor PM1, which is VD2, and VINT may be negative and less than threshold voltage of PM1(VTH1), that is VD2−VINT<VTH1. For example, the voltage differential between the gate of the first PMOS transistor PM2, which is VD1, and VINT may be negative and less than threshold voltage of PM2(VTH2), that is VD1−VINT<VTH2). As the first PMOS transistor PM1 and the second PMOS transistor PM2 are turned on, the amplifying circuit 130 may amplify the voltage difference dVD between the voltage levels of the first data voltage level VD1 and the second data voltage level VD2. In the sensing period, the first data voltage level VD1 may become higher than that at the third time point t13 and may then be maintained uniformly; the second data voltage level VD2 may become lower than that at the third time point t13 and may then be maintained uniformly.

In the sensing period, the bitline sensing amplifier 100 may determine data stored in the memory cells MC1 and MC2. In an embodiment, the bitline sensing amplifier 100 may determine data of the first memory cell MC1, based on a relationship between a decision voltage level DV and the first data voltage level VD1 corresponding to the first memory cell MC1. For example, when the first data voltage level VD1 is greater than the decision voltage level DV, the bitline sensing amplifier 100 may determine that data 1 is stored in the first memory cell MC1. In another example, unlike the example illustrated in FIG. 6, when data 0 is stored in the first memory cell MC1, the bitline sensing amplifier 100 may determine that data 0 is stored in the first memory cell MC1, based on the condition that the first data voltage level VD1 is less than the decision voltage level DV.

A period from t14 to t15 may be a precharge period. At the fourth time point t14, the equalization signal PEQ may transition from LOW to HIGH, and the control signal CS may transition from HIGH to LOW. In an embodiment, in the precharge period, a difference between threshold voltages of the first NMOS transistor NM1 and the second NMOS transistor NM2 may be applied to the bitline voltage levels VB1 and VB2.

For example, the voltages of the second node N12 and the third node N13 may transition to the equalization voltage VEQ in response to the equalization signal PEQ and the voltage levels of the gate and drain nodes of each of the first NMOS transistor NM1 and the second NMOS transistor NM2 are equalized. The first NMOS transistor NM1 and the second NMOS transistor NM2 effectively form a diode connection. The source node of each of the first NMOS transistor NM1 and the second NMOS transistor NM2 that effectively form the diode connection may have a voltage level that is less than the voltage level of the gate node by at least as much as the threshold voltage. For example, the first bitline voltage level VB1 and the second bitline voltage level VB2 are the same as a voltage level obtained by subtracting the threshold voltages of the first NMOS transistor NM1 and the second NMOS transistor NM2 from the first data voltage level VD1 and the second data voltage level VD2, respectively. Through the above manner, offset information of each of the first NMOS transistor NM1 and the second NMOS transistor NM2 (e.g., threshold voltage information of each of the first NMOS transistor NM1 and the second NMOS transistor NM2) may be applied to the bitline voltage levels VB1 and VB2.

According to the operation described with reference to FIGS. 2 to 6, the bitline sensing amplifier 100 may perform the operations at the first time point t11 to the fifth time point t15 with respect to the remaining memory cells other than the first memory cell MC1 and may transfer data stored in relevant memory cells to the input/output circuit 1500 or IO. Likewise, even when data 0 is stored in the first memory cell MC1, data may be transferred to the input/output circuit 1500 or IO to be read using the same as the above method. However, in the case of the read operation on the first memory cell MC1 in which data 0 is stored, the waveforms of the first data voltage level VD1 and the second data voltage level VD2 of FIG. 6 may be mutually changed. That is, in the clamping period, the second data voltage level VD2 may be clamped to the equalization voltage VEQ, and the first data voltage level VD1 may decrease; after the amplification operation of the sensing period, the bitline sensing amplifier 100 may determine that data 0 is stored in the first memory cell MC1, based on the condition that the first data voltage level VD1 is less than the decision voltage level DV.

Based on the above operation, the bitline sensing amplifier 100 may transfer data stored in memory cells to the input/output circuit 1500 or IO. The bitline sensing amplifier 100 according to embodiments of the present disclosure may directly sense currents flowing to the first bitline BL and the second bitline BLB in a state where the first bitline BL and the second bitline BLB are not directly connected to the gate nodes of transistors included in the bitline sensing amplifier 100 (i.e., in a state where the first bitline BL and the second bitline BLB are connected to the source node of the first NMOS transistor NM1 and the source node of the second NMOS transistor NM2). The bitline sensing amplifier 100 may convert a difference between the sensed currents into a voltage level (e.g., the first data voltage level VD1 or the second data voltage level VD2) based on the difference between the sensed currents such that data is transferred to the input/output circuit 1500 or IO. The bitline sensing amplifier 100 may read data more quickly by removing the offsets of the first NMOS transistor NM1 and the second NMOS transistor NM2 in the precharge period. The time points t10 to t15 which are illustrated in FIG. 6 and are described with reference to FIG. 6 indicate a temporal sequence, but it should not be understood that time intervals between the time points t10 to t15 illustrated in FIG. 6 indicate relative time lengths where actual operations are performed.

The bitline sensing amplifier 100 described with reference to FIGS. 2 to 6 may write data in the first memory cell MC1 through the second read/write circuit 110B. In this case, because the equalization operation and the sensing operation are not required, both the equalization signal PEQ and the control signal CS may be at LOW. The write enable signal WE of the second read/write circuit 110B in the bitline sensing amplifier 100 may be set to HIGH such that data (e.g., data 1 or data 0) to be written in the first memory cell MC1 are provided.

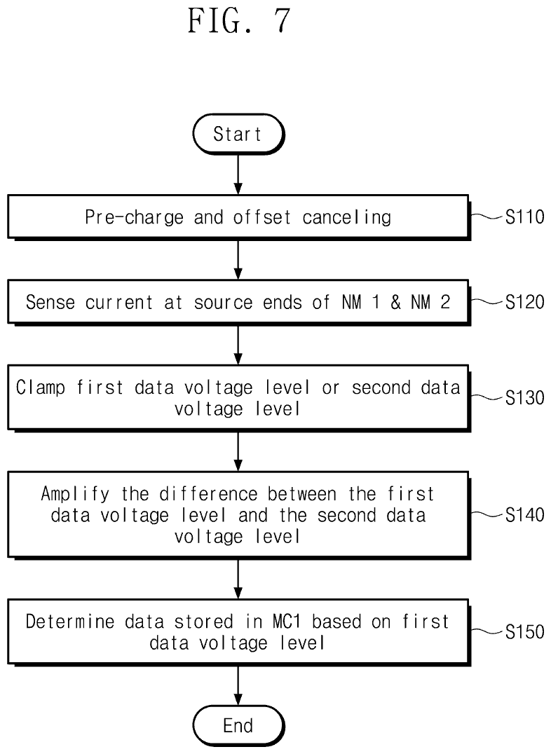

FIG. 7 is a flowchart illustrating a read operation sequence of the bitline sensing amplifier 100 of FIG. 3, according to an embodiment of the present disclosure. A read operation sequence of the bitline sensing amplifier 100 according to an embodiment of the present disclosure will be described with reference to FIGS. 2 to 7.

Referring to FIGS. 2 to 7, in operation S110, the bitline sensing amplifier 100 may perform a precharge and offset cancellation operation. For example, as the equalization voltage VEQ is provided to the second node N12 and the third node N13 through the equalization circuit 120 of FIG. 4, the precharge operation may be performed.

The first NMOS transistor NM1 and the second NMOS transistor NM2 may have the effective diode connection structure depending on the precharge operation. The first bitline voltage level VB1 may have a voltage level obtained by subtracting the threshold voltage of the first NMOS transistor NM1 from the equalization voltage VEQ, and likewise, the second bitline voltage level VB2 may have a voltage level obtained by subtracting the threshold voltage of the second NMOS transistor NM2 from the equalization voltage VEQ. The offset cancellation operation may be performed (e.g., a difference between the threshold voltages of the first NMOS transistor NM1 and the second NMOS transistor NM2 may be removed) based on the formation of the first bitline voltage level VB1 and the second bitline voltage level VB2.

In operation S120, the bitline sensing amplifier 100 may sense a current flowing to each of the first NMOS transistor NM1 and the second NMOS transistor NM2. In this case, the turn-on voltage may be applied to the wordlines WL1 and WL2 connected to the memory cells MC1 and MC2. In an embodiment, the bitline sensing amplifier 100 may sense the first current IB1 and the second current IB2 through source ends of transistors included in the amplifying circuit 130. The bitline sensing amplifier 100 may sense the first current IB1 flowing to the first bitline BL through the source end of the first NMOS transistor NM1 (i.e., through the fourth node N14) and may sense the second current IB2 flowing to the second bitline BLB through the source end of the second NMOS transistor NM2 (i.e., through the fifth node N15).

In operation S130, the bitline sensing amplifier 100 may clamp the first data voltage level VD1. For example, when data 1 is stored in the first memory cell MC1, because the first current IB1 flows to the first NMOS transistor NM1, the second data voltage level VD2 may decrease (e.g., may decrease at a higher rate than the first data voltage level VD1 because the first current IB1 is larger than the second current IB2). The second NMOS transistor NM2 may be turned off in response to the second data voltage level VD2 decreases. As the second NMOS transistor NM2 is turned off, the first data voltage level VD1 may be clamped without a voltage change.

For another example, when data 0 is stored in the first memory cell MC1, because the second current IB2 flows to the second NMOS transistor NM2, the first data voltage level VD1 may decrease (e.g., may decrease at a higher rate than the second data voltage level VD2 because the second current IB2 is larger than the first current IB1), and the first NMOS transistor NM1 may be turned off in response thereto. As the first NMOS transistor NM1 is turned off, the second data voltage level VD2 may be clamped.

In operation S140, the bitline sensing amplifier 100 may amplify a difference between the first data voltage level VD1 and the second data voltage level VD2. The bitline sensing amplifier 100 may perform the amplification operation through the amplifying circuit 130. For example, as the power supply voltage is supplied to the first node N11, the bitline sensing amplifier 100 may supply the power to the amplifying circuit 130 and may amplify the difference between the first data voltage level VD1 and the second data voltage level VD2.

In operation S150, the bitline sensing amplifier 100 may determine data of a memory cell, based on the first data voltage level VD1 thus amplified. For example, referring to FIG. 6 together, when data 1 is stored in the first memory cell MC1, the bitline sensing amplifier 100 may determine that data 1 is stored in the first memory cell MC1, based on the condition that the first data voltage level VD1 is greater than the decision voltage level DV. For another example, when data 0 is stored in the first memory cell MC1, the bitline sensing amplifier 100 may determine that data 0 is stored in the first memory cell MC1, based on the condition that the first data voltage level VD1 is less than the decision voltage level DV.

The bitline sensing amplifier 100 may read data stored in the first memory cell MC1, based on the above operation. FIG. 7 is illustrated and described based on the case where the second memory cell MC2 is the reference cell and data are read from the first memory cell MC1, but the present disclosure is not limited thereto. For example, according to some embodiments, the first memory cell MC1 may be the reference cell and data may be read from the second memory cell MC2.

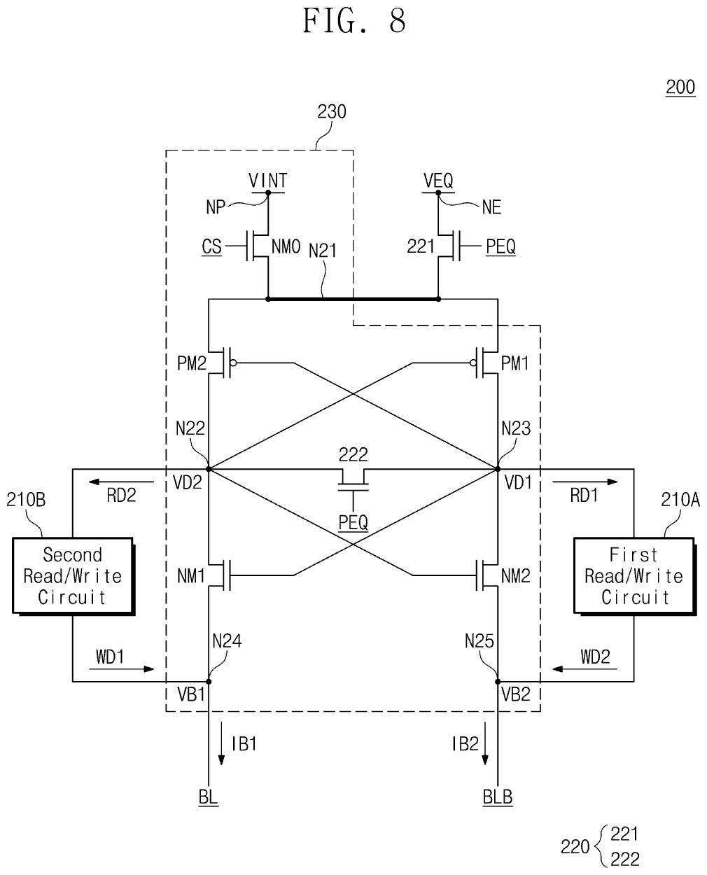

FIG. 8 is a circuit diagram illustrating a bitline sensing amplifier of FIG. 2, according to an embodiment of the present disclosure. Referring to FIG. 8, a bitline sensing amplifier 200 may include a first read/write circuit 210A, a second read/write circuit 210B, an equalization circuit 220, and an amplifying circuit 230. The bitline sensing amplifier 200 according to an embodiment of the present disclosure will be described with reference to FIGS. 2 and 8.

The first read/write circuit 210A or the second read/write circuit 210B may correspond to the first read/write circuit 110A or the second read/write circuit 110B of FIG. 3. For example, the first read/write circuit 210A may be provided with the first read data RD1 or may provide the second write data WD2, and the second read/write circuit 210B may be provided with the second read data RD2 or may provide the first write data WD1. The structure of the first read/write circuit 210A or the second read/write circuit 210B may be the same as the structure of FIG. 4, and operations of the first read/write circuit 210A or the second read/write circuit 210B may be the same as or similar to the operations of the first read/write circuit 110A or the second read/write circuit 110B described with reference to FIGS. 1 to 7.

The equalization circuit 220 may equalize voltages of a second node N22 and a third node N23. Referring to FIG. 8, the equalization circuit 220 may include a first transistor 221 and a second transistor 222. The first transistor 221 may operate in response to the equalization signal PEQ and may be connected between the equalization node NE and a first node N21. The second transistor 222 may operate in response to the equalization signal PEQ and may be connected between the second node N22 and the third node N23.

The first transistor 221 may provide a specific voltage level to the first node N21 in response to the equalization signal PEQ. In an embodiment, a voltage of the equalization node NE may be the equalization voltage VEQ. For example, the first transistor 221 may be turned on in response to the equalization signal PEQ and may provide the equalization voltage VEQ to the first transistor 221.

In this case, as a difference between the second data voltage level VD2 and the voltage level of the first node N21 increases, the first PMOS transistor PM1 may be turned on. As the first PMOS transistor PM1 is turned on, the first data voltage level VD1 may become the voltage level of the first node N21. For example, the first PMOS transistor PM1 may be turned on, and thus, the first data voltage level VD1 may become the equalization voltage VEQ.

The second transistor 222 may be turned on in response to the equalization signal PEQ such that the voltage levels of the second node N22 and the third node N23 are equalized. For example, the second transistor 222 may be turned on in response to the equalization signal PEQ such that the second data voltage level VD2 of the second node N22 becomes the equalization voltage VEQ. After the precharge operation, based on the above structure and operation, the equalization circuit 220 may equalize the first data voltage level VD1 and the second data voltage level VD2 with the equalization voltage VEQ.

The amplifying circuit 230 may amplify a difference between the first data voltage level VD1 and the second data voltage level VD2 generated based on the current sensing of the bitlines BL and BLB. The amplifying circuit 230 may correspond to the amplifying circuit 130 of FIG. 3. An operation of the amplifying circuit 230 may be similar to the operation of the amplifying circuit 130 described with reference to FIGS. 3 to 7. That is, the amplifying circuit 230 may transfer data of the first memory cell MC1 or the second memory cell MC2 to the first read/write circuit 210A or the second read/write circuit 210B or may be provided with data to be written in the first memory cell MC1 or the second memory cell MC2 from the first read/write circuit 210A or the second read/write circuit 210B.

In an embodiment, the amplifying circuit 230 may include a plurality of transistors. For example, the amplifying circuit 230 may include three NMOS transistors NM0, NM1, and NM2 and two PMOS transistors PM1 and PM2. The NMOS transistors NM0, NM1, and NM2 and the PMOS transistors PM1 and PM2 of the amplifying circuit 230 may respectively correspond to the NMOS transistors NM0, NM1, and NM2 and the PMOS transistors PM1 and PM2 of FIG. 3 and may have the same connection structure as the NMOS transistors NM0, NM1, and NM2 and the PMOS transistors PM1 and PM2 of FIG. 3. For example, the first PMOS transistor PM1 may include a gate node connected to the second node N22 and may be connected between the first node N21 and the third node N23. For another example, the first NMOS transistor NM1 may include a gate node connected to the third node N23 and may be connected between the second node N22 and a fourth node N24.

The bitline sensing amplifier 200 of FIG. 8 may sense data of the memory cells MC1 and MC2 in a method the same as the method described with reference to FIGS. 6 and 7. For example, in the precharge period, the bitline sensing amplifier 200 may equalize the first data voltage level VD1 and the second data voltage level VD2 with the equalization voltage VEQ in response to that the equalization signal PEQ transitions to HIGH; the bitline sensing amplifier 200 may determine the data stored in the first memory cell MC1 or the second memory cell MC2 by sequentially performing the operations of the sampling, clamping, and sensing periods of FIG. 6.

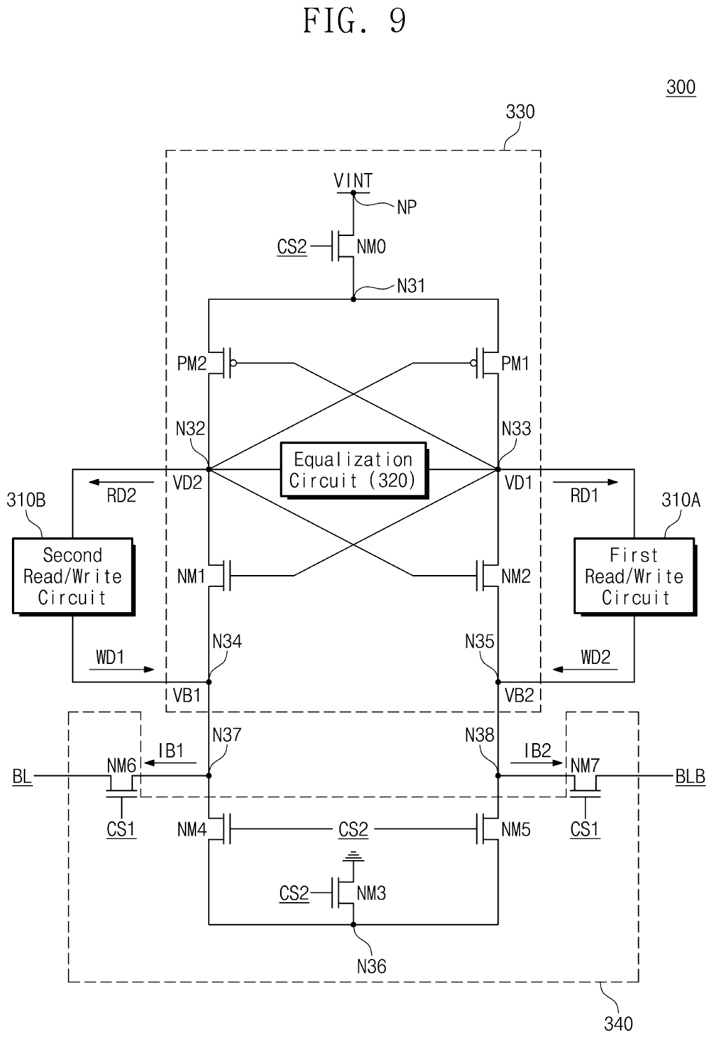

FIG. 9 is a circuit diagram illustrating a bitline sensing amplifier of FIG. 2, according to an embodiment of the present disclosure. Referring to FIG. 9, a bitline sensing amplifier 300 may include a first read/write circuit 310A, a second read/write circuit 310B, an equalization circuit 320, a first amplifying circuit 330, and a second amplifying circuit 340. The bitline sensing amplifier 300 according to an embodiment of the present disclosure will be described in detail with reference to FIGS. 2 and 9.

The first read/write circuit 310A or the second read/write circuit 310B may correspond to the first read/write circuit 110A or the second read/write circuit 110B of FIG. 3. For example, the first read/write circuit 310A may be provided with the first read data RD1 or may provide the second write data WD2, and the second read/write circuit 310B may be provided with the second read data RD2 or may provide the first write data WD1. The structure of the first read/write circuit 310A or the second read/write circuit 310B may be the same as the structure of FIG. 4, and operations of the first read/write circuit 310A or the second read/write circuit 310B may be the same as or similar to the operations of the first read/write circuit 110A/210A or the second read/write circuit 110B/210B described with reference to FIGS. 3, 4, and 6 to 8.

The equalization circuit 320 may equalize voltages of a second node N32 and a third node N33. The equalization circuit 320 may correspond to the equalization circuit 120 of FIG. 3 and may include the structure of the equalization circuit 120 of FIG. 5. An operation of the equalization circuit 320 may be the same as or similar to the operation of the equalization circuit 120/220 described with reference to FIGS. 3 and 5 to 8.

The first amplifying circuit 330 may amplify a difference between the first data voltage level VD1 and the second data voltage level VD2 generated based on currents of the bitlines BL and BLB. The first amplifying circuit 330 may correspond to the amplifying circuit 130 of FIG. 3 or the amplifying circuit 230 of FIG. 8. An operation of the first amplifying circuit 330 may be the same as or similar to the operation of the amplifying circuit 130/230 described with reference to FIGS. 3 to 8. That is, the first amplifying circuit 330 may transfer data of the first memory cell MC1 or the second memory cell MC2 to the first read/write circuit 310A or the second read/write circuit 310B or may be provided with data to be written in the first memory cell MC1 or the second memory cell MC2 from the first read/write circuit 310A or the second read/write circuit 310B.

In an embodiment, the first amplifying circuit 330 may include a plurality of transistors. For example, the first amplifying circuit 330 may include three NMOS transistors NM0, NM1, and NM2 and two PMOS transistors PM1 and PM2. The NMOS transistors NM0, NM1, and NM2 and the PMOS transistors PM1 and PM2 of the first amplifying circuit 330 may respectively correspond to the NMOS transistors NM0, NM1, and NM2 and the PMOS transistors PM1 and PM2 of FIG. 3 and may have the same connection structure as the NMOS transistors NM0, NM1, and NM2 and the PMOS transistors PM1 and PM2 of FIG. 3. For example, the second PMOS transistor PM2 may include a gate node connected to the third node N33 and may be connected between a first node N31 and the second node N32. For another example, the first NMOS transistor NM1 may include a gate node connected to the third node N33 and may be connected between the second node N32 and a fourth node N34, and the 0-th NMOS transistor NM0 may operate in response to a second control signal CS2 and may be connected between the power node NP and the first node N31.

The second amplifying circuit 340 may be connected to the first amplifying circuit 330 and may be implemented to connect the first bitline BL and the second bitline BLB to the first amplifying circuit 330. In an embodiment, the second amplifying circuit 340 may be connected to the first amplifying circuit 330, based on the connection with source ends of transistors which the first amplifying circuit 330 includes. For example, a seventh node N37 of the second amplifying circuit 340 may be connected to the fourth node N34 being the source end of the first NMOS transistor NM1 included in the first amplifying circuit 330. Likewise, an eighth node N38 of the second amplifying circuit 340 may be connected to a fifth node N35 being the source end of the second NMOS transistor NM2 included in the first amplifying circuit 330. The second amplifying circuit 340 may be connected to the first amplifying circuit 330, based on the connection between respective nodes. Based on the connection with the first amplifying circuit 330, the second amplifying circuit 340 may connect the first amplifying circuit 330 and the first bitline BL and the second bitline BLB or may connect the first amplifying circuit 330 and the memory cells MC1 and MC2 through the bitlines BL and BLB.

The second amplifying circuit 340 may accelerate the amplification of the difference between the first data voltage level VD1 and the second data voltage level VD2 of the first amplifying circuit 330 In an embodiment, the second amplifying circuit 340 may disconnect the bitline sensing amplifier 300 from the bitlines BL and BLB. Referring to FIG. 9, the second amplifying circuit 340 may include third to seventh NMOS transistors NM3 to NM7. An operation of the second amplifying circuit 340 will be described in detail together with the third to seventh NMOS transistors NM3 to NM7.

The third NMOS transistor NM3 may connect the second amplifying circuit 340 and a ground node. The third NMOS transistor NM3 may be connected between the ground node and a sixth node N36; like the 0-th NMOS transistor NM0, the third NMOS transistor NM3 may operate in response to the second control signal CS2. When the third NMOS transistor NM3 is turned on, the second amplifying circuit 340 may start to accelerate the amplification of the difference between the first data voltage level VD1 and the second data voltage level VD2 of the first amplifying circuit 330.

The fourth NMOS transistor NM4 may be connected between the sixth node N36 and the seventh node N37 connected to the fourth node N34 and may operate in response to the second control signal CS2. The fifth NMOS transistor NM5 may be connected between the sixth node N36 and the eighth node N38 connected to the fifth node N35 and may operate in response to the second control signal CS2. The fourth NMOS transistor NM4 and the fifth NMOS transistor NM5 may accelerate the amplification of the difference between the first data voltage level VD1 and the second data voltage level VD2 of the first amplifying circuit 330.

The sixth NMOS transistor NM6 may be connected between the seventh node N37 and the first bitline BL and may operate in response to a first control signal CS1. The first control signal CS1 and the second control signal CS2 may be complementary to each other. For example, when the second control signal CS2 is at HIGH, the first control signal CS1 may be at LOW; when the second control signal CS2 is at LOW, the first control signal CS1 may be at HIGH. The second control signal CS2 may correspond to the control signal CS of FIGS. 3 and 6 to 8.

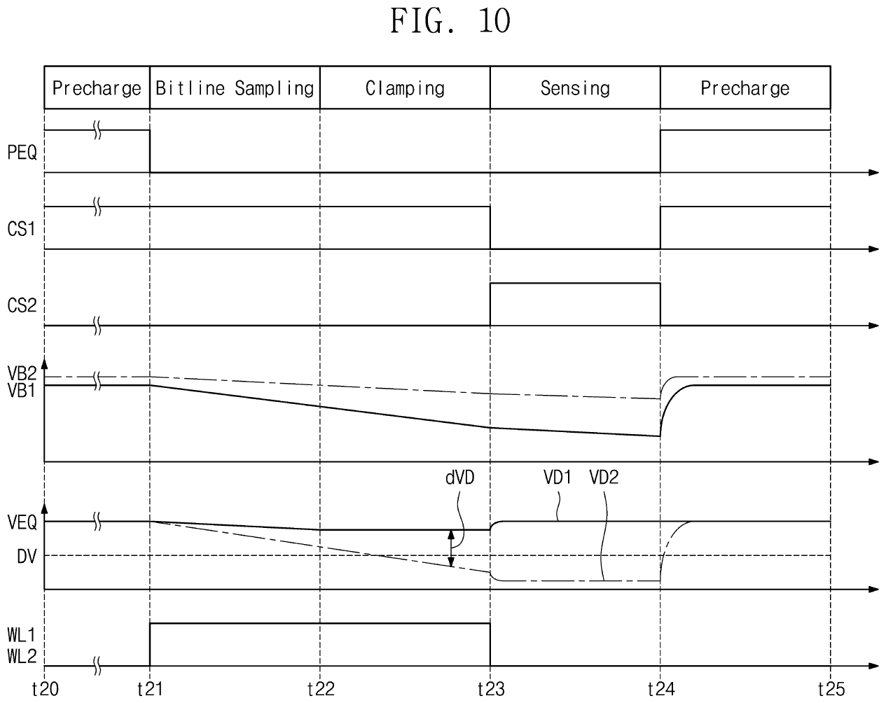

The seventh NMOS transistor NM7 may be connected between the eighth node N38 and the second bitline BLB and may operate in response to the first control signal CS1. The sixth NMOS transistor NM6 and the seventh NMOS transistor NM7 may disconnect the bitline sensing amplifier 300 from the bitlines BL and BLB. Accordingly, the bitline sensing amplifier 300 may accelerate the amplification of the difference between the first data voltage level VD1 and the second data voltage level VD2. An operation of the second amplifying circuit 340 will be described in detail with reference to FIG. 10.

FIG. 10 is a timing diagram illustrating how signals and voltages change over time during the read operation of the bitline sensing amplifier 300 of FIG. 9, according to an embodiment of the present disclosure. An example of the read operation of the bitline sensing amplifier 300 according to an embodiment of the present disclosure will be described with reference to FIGS. 2, 4, 5, 9, and 10. FIG. 10 will be described based on the case where data 1 is stored in the first memory cell MC1, but the present disclosure is not limited thereto. In FIG. 10, because the bitline sensing amplifier 300 performs the read operation, the write enable signal WE may be at LOW throughout the whole operation.

A time period from t20 to t21 may be a precharge period. In the precharge period, because the bitline sensing amplifier 300 performs the same operation as described with reference to FIG. 6, the first data voltage level VD1 and the second data voltage level VD2 may reach the equalization voltage VEQ. An operation in the precharge period will be described in detail through a time period from t24 to t25. In FIG. 10, signals before wave patterns are for showing respective signals or voltage levels at the first time point t21, and the present disclosure is not limited to the signals before the wave patterns illustrated in FIG. 10.

In the precharge period, as the first control signal CS1 of the bitline sensing amplifier 300 is maintained at HIGH, the bitline sensing amplifier 300 and the first bitline BL and the second bitline BLB may be connected. The second control signal CS2 may maintain the LOW state opposite to that of the first control signal CS1.

A time period from t21 to t22 may be a bitline sampling period. In the bitline sampling period, the wordlines WL1 and WL2 may be at HIGH. When the wordlines WL1 and WL2 are at HIGH, the first current IB1 and the second current IB2 may flow within the memory cells MC1 and MC2. Like the bitline sampling period of the bitline sensing amplifier 100 of FIG. 6, the first data voltage level VD1 may decrease in response to the first current IB1, and the second data voltage level VD2 may decrease in response to the second current IB2.

In the bitline sampling period, the equalization signal PEQ may transition to LOW (e.g., at the second time point t22). The second control signal CS2 may maintain LOW, and the first control signal CS1 may maintain HIGH. As the first control signal CS1 is maintained at HIGH, the bitline sensing amplifier 300 may maintain the connection with the bitlines BL and BLB.

In an embodiment, at the second time point t22 being an end point of the bitline sampling period, the first data voltage level VD1 may be clamped in response to the second NMOS transistor NM2 being turned off due to the drop in voltage at VD2 which is connected to the gate of the second NMOS transistor NM2. This is that, as described with reference to FIG. 6, because the first current IB1 is larger than the second current IB2, the second data voltage level VD2 decreases to be faster than the first data voltage level VD1.

A time period from t22 to t23 may be a clamping period. The bitline sensing amplifier 300 may operate like the bitline sensing amplifier 100 of FIG. 6. Like the bitline sampling period, the equalization signal PEQ and the second control signal CS2 may maintain LOW, and the first control signal CS1 and the wordlines WL1 and WL2 may maintain HIGH.

A time period from t23 to t24 may be a sensing period. The bitline sensing amplifier 300 may operate to be similar to the bitline sensing amplifier 100 of FIG. 6. In an embodiment, in the sensing period, the bitline sensing amplifier 300 may be disconnected from the bitlines BL and BLB. For example, at the third time point t23, the first control signal CS1 of the bitline sensing amplifier 300 may transition to LOW. As the sixth NMOS transistor NM6 and the seventh NMOS transistor NM7 are turned off in response to the first control signal CS1, the bitline sensing amplifier 300 may be disconnected from the bitlines BL and BLB.

The second control signal CS2 may transition to HIGH; in this case, as the power is supplied to the first node N11, like the operation in the sensing period of the amplifying circuit 130 of FIG. 6, the first amplifying circuit 330 may start the amplification of the voltage difference dVD between the first data voltage level VD1 and the second data voltage level VD2. The third NMOS transistor NM3 may be turned on in response to the second control signal CS2, and thus, the ground voltage may be provided to the sixth node N36. Likewise, the 0-th NMOS transistor NM0 may be turned on in response to the second control signal CS2, and thus, the power supply voltage may be provided to the first node N31. The fourth NMOS transistor NM4 and the fifth NMOS transistor NM5 may be turned on in response to the second control signal CS2, and the second amplifying circuit 340 may further accelerate the amplification operation of the voltage difference dVD between the voltage levels of the first data voltage level VD1 and the second data voltage level VD2.

In the sensing period, the wordlines WL1 and WL2 may be maintained at LOW, and the equalization signal PEQ may maintain the LOW state. Like FIG. 6, the bitline sensing amplifier 300 may determine data stored in the first memory cell MC1, depending on whether the first data voltage level VD1 thus amplified is greater than the decision voltage level DV or is less than the decision voltage level DV.

A time period from t24 to t25 may be a precharge period. The bitline sensing amplifier 300 may operate to be similar to the precharge period of the bitline sensing amplifier 100 of FIG. 6. In an embodiment, in the precharge period, the bitline sensing amplifier 300 may be again connected to the bitlines BL and BLB. For example, the first control signal CS1 may transition to HIGH at the fourth time point t24 such that the sixth NMOS transistor NM6 and the seventh NMOS transistor NM7 are turned on; in this case, the bitline sensing amplifier 300 may be connected to the bitlines BL and BLB. Like the bitline sensing amplifier 100 of FIG. 6, the bitline sensing amplifier 300 may perform the offset cancellation operation in the precharge period.

The bitline sensing amplifier 300 described with reference to FIGS. 9 and 10 may perform the data read operation of an arbitrary memory cell, based on the operations at the first time point t21 to the fifth time point t25. Like the bitline sensing amplifier 100 of FIG. 6, the bitline sensing amplifier 300 may perform the data write operation of a memory cell. Unlike the bitline sensing amplifier 100 of FIG. 3, the bitline sensing amplifier 300 described with reference to FIGS. 9 and 10 may be disconnected from the first bitline BL and the second bitline BLB and thus may further accelerate the amplification of a voltage difference between the first data voltage level VD1 and the second data voltage level VD2. Also, as the second amplifying circuit 340 provides currents to the fourth node N34 and the fifth node N35 through the fourth NMOS transistor NM4 and the fifth NMOS transistor NM5, the amplification of the first amplifying circuit 330 may be further accelerated. The time points t20 to t25 described with reference to FIG. 10 are for showing the sequence of operations, and it does not indicate that time intervals between the time points t20 to t25 indicate relative sizes of time intervals during where the operations are performed.

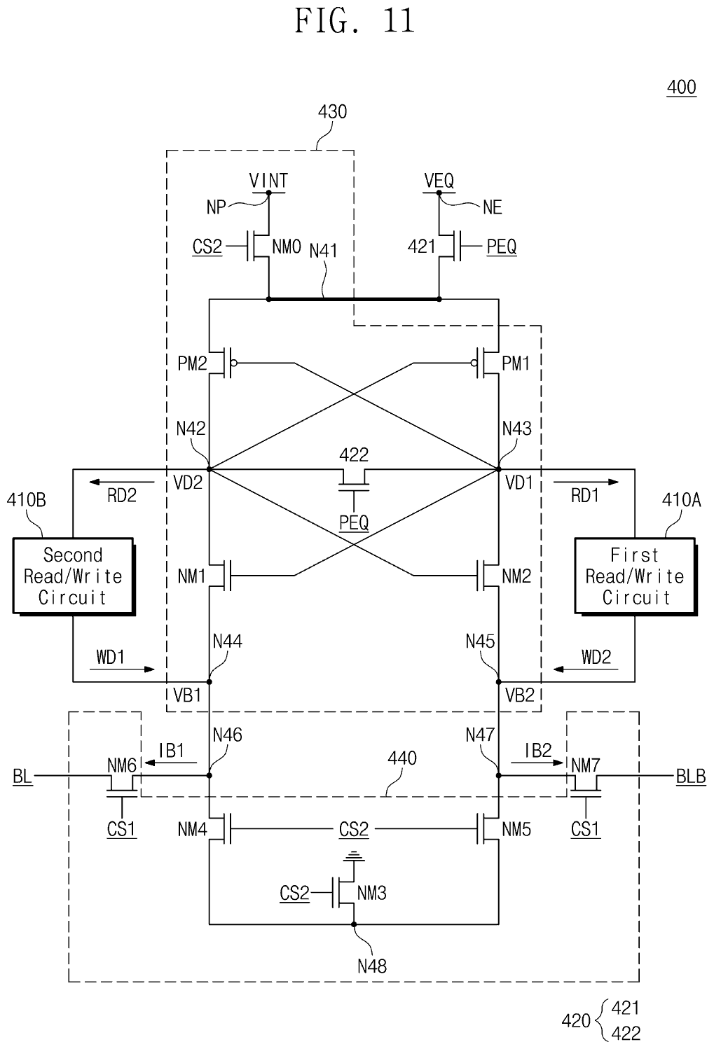

FIG. 11 is a circuit diagram illustrating a bitline sensing amplifier of FIG. 2 in detail, according to an embodiment of the present disclosure. Referring to FIG. 11, a bitline sensing amplifier 400 may include a first read/write circuit 410A, a second read/write circuit 410B, an equalization circuit 420, a first amplifying circuit 430, and a second amplifying circuit 440. The bitline sensing amplifier 400 according to an embodiment of the present disclosure will be described in detail with reference to FIGS. 2 and 11.

The first read/write circuit 410A or the second read/write circuit 410B may correspond to the first read/write circuit 110A or the second read/write circuit 110B of FIG. 3. For example, the first read/write circuit 410A may be provided with the first read data RD1 or may provide the second write data WD2, and the second read/write circuit 410B may be provided with the second read data RD2 or may provide the first write data WD1. The structure of the first read/write circuit 410A or the second read/write circuit 410B may be the same as the structure of FIG. 4, and operations of the first read/write circuit 410A or the second read/write circuit 410B may be the same as or similar to the operations of the first read/write circuit 110A/210A/310A or the second read/write circuit 110B/210B/310B described with reference to FIGS. 3, 4, and 6 to 10.

The equalization circuit 420 may equalize voltages of a second node N42 and a third node N43 and may correspond to the equalization circuit 220 of FIG. 8. Referring to FIG. 11, the equalization circuit 420 may include a first transistor 421 and a second transistor 422. The first transistor 421 may operate in response to the equalization signal PEQ and may be connected between the equalization node NE and a first node N41. The second transistor 422 may operate in response to the equalization signal PEQ and may be connected between the second node N42 and the third node N43. The equalization circuit 420 may operate in a method the same as or similar to that of the equalization circuit 220 of FIG. 8 and may equalize voltage levels of the second node N42 and the third node N43 with the equalization voltage VEQ.

The first amplifying circuit 430 may amplify a difference between the first data voltage level VD1 and the second data voltage level VD2 generated based on currents of the bitlines BL and BLB. The first amplifying circuit 430 may correspond to the amplifying circuit 130 or 230 of FIG. 3 or 8 or the first amplifying circuit 330 of FIG. 9. An operation of the first amplifying circuit 430 may be the same as or similar to the operation of the amplifying circuit 130 or 230 described with reference to FIGS. 3 and 6 to 8 or the operation of the first amplifying circuit 330 described with reference to FIGS. 9 and 10. The first amplifying circuit 430 may transfer data of the first memory cell MC1 or the second memory cell MC2 to the first read/write circuit 410A or the second read/write circuit 410B or may be provided with data to be written in the first memory cell MC1 or the second memory cell MC2 from the first read/write circuit 410A or the second read/write circuit 410B.

In an embodiment, the first amplifying circuit 430 may include a plurality of transistors. For example, the first amplifying circuit 430 may include three NMOS transistors NM0, NM1, and NM2 and two PMOS transistors PM1 and PM2. The NMOS transistors NM0, NM1, and NM2 and the PMOS transistors PM1 and PM2 of the first amplifying circuit 430 may respectively correspond to the NMOS transistors NM0, NM1, and NM2 and the PMOS transistors PM1 and PM2 of FIG. 3 or 8 and may have the same connection structure as the NMOS transistors NM0, NM1, and NM2 and the PMOS transistors PM1 and PM2 of FIG. 3 or 8. For example, the second PMOS transistor PM2 may include a gate node connected to the third node N43 and may be connected between the first node N41 and the second node N42. For another example, the second NMOS transistor NM2 may include a gate node connected to the third node N43 and may be connected between the second node N42 and a fourth node N44.

The second amplifying circuit 440 may be connected to the first amplifying circuit 430 and may be implemented to connect the first bitline BL and the second bitline BLB to the first amplifying circuit 430. The second amplifying circuit 440 may correspond to the second amplifying circuit 340 of FIG. 9. For example, like the second amplifying circuit 340 of FIG. 9, the second amplifying circuit 440 may be connected to the first amplifying circuit 430, based on the condition that the fourth node N44 and a sixth node N46 are connected and on the condition that a fifth node N45 and a seventh node N47 are connected. Based on the connection with the first amplifying circuit 430, the second amplifying circuit 440 may connect the first amplifying circuit 430 and the first bitline BL and the second bitline BLB or may connect the first amplifying circuit 430 and the memory cells MC1 and MC2 through the bitlines BL and BLB.

Like the second amplifying circuit 340 of FIG. 9, the second amplifying circuit 440 may accelerate the amplification of the difference between the first data voltage level VD1 and the second data voltage level VD2 of the first amplifying circuit 430. In an embodiment, like the second amplifying circuit 340 of FIG. 9, the second amplifying circuit 440 may connect or disconnect the bitline sensing amplifier 400 to or from the bitlines BL and BLB. An operation of the second amplifying circuit 440 may be the same as or similar to the operation of the second amplifying circuit 340 described with reference to FIGS. 9 and 10.

In an embodiment, the second amplifying circuit 440 may include a plurality of transistors. For example, the second amplifying circuit 440 may include five NMOS transistors NM3 to NM7. The NMOS transistors NM3 to NM7 of the second amplifying circuit 440 may respectively correspond to the NMOS transistors NM3 to NM7 of FIG. 9 and may have the same connection structure as the NMOS transistors NM3 to NM7 of FIG. 9. For example, the third NMOS transistor NM3 may operate in response to the second control signal CS2 and may be connected between the ground node and an eighth node N48, and the seventh NMOS transistor NM7 may operate in response to the first control signal CS1 and may be connected between the second bitline BLB and the seventh node N47.

The bitline sensing amplifier 400 of FIG. 11 may operate in a method similar to that of the bitline sensing amplifier 300 of FIG. 9. For example, the bitline sensing amplifier 400 may read data of the memory cells MC1 and MC2 by sensing currents of the first bitline BL and the second bitline BLB and amplifying a difference between the first data voltage level VD1 and the second data voltage level VD2 in the method described with reference to FIGS. 7, 9, and 10. The bitline sensing amplifier 400 may write data in the memory cells MC1 to MC2 in a method similar to that of the bitline sensing amplifier 300 of FIG. 9.

The NMOS transistors and the PMOS transistors illustrated in FIGS. 3 to 11 and described with reference to FIGS. 3 to 11 are provided as an example, and the present disclosure is not limited thereto. It should be understood that the NMOS transistors and the PMOS transistors are able to be replaced with other types of transistors within a range where the bitline sensing amplifier 100/200/300/400 operates, and it should be understood that the signals described with reference to FIGS. 6 and 10 are able to be changed depending on the replaced transistors to implement the operations of the above embodiments.

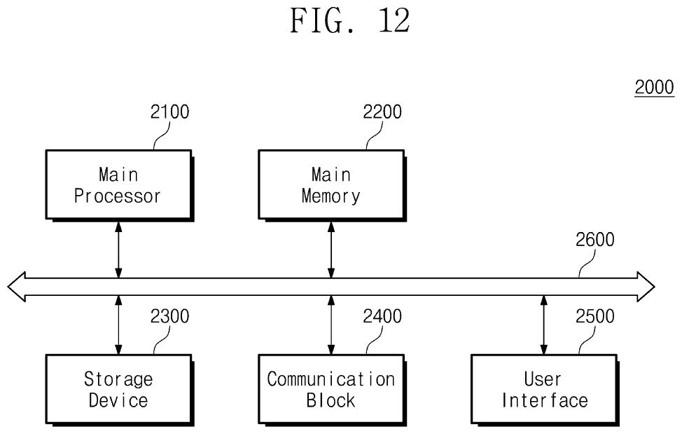

FIG. 12 is a block diagram illustrating a configuration of an electronic system according to an embodiment. An electronic system 2000 may include a main processor 2100, a main memory 2200, a storage device 2300, a communication block 2400, and a user interface 2500. For example, the electronic system 2000 may be one of electronic devices such as a desktop computer, a laptop computer, a tablet computer, a smartphone, a wearable device, a video game console, a workstation, and a server.

The main processor 2100 may control all operations of the electronic system 2000. The main processor 2100 may perform various kinds of arithmetic operations and/or logic operations. To this end, the main processor 2100 may include a special-purpose circuit (e.g., a field programmable gate array (FPGA) or an application specific integrated circuits (ASICs)). For example, the main processor 2100 may include one or more processor cores and may be implemented with a general-purpose processor, a special-purpose processor, or an application processor.

The main memory 2200 may store data which are used in the operation of the electronic system 2000. For example, the main memory 2200 may temporarily store data processed or to be processed by the main processor 2100. For example, the main memory 2200 may include a volatile memory such as a dynamic DRAM (DRAM) or a synchronous DRAM (SDRAM) and/or a non-volatile memory such as a phase-change RAM (PRAM), a magneto-resistive RAM (MRAM), a resistive RAM (ReRAM), or a ferroelectric RAM (FRAM). In an embodiment, the main memory 2200 may be the memory device 1000 described with reference to FIGS. 1 to 11 or may include the memory device 1000.

The storage device 2300 may include a memory device and a controller. The memory device of the storage device 2300 may store data regardless of whether power is supplied. For example, the storage device 2300 may include a non-volatile memory such as a flash memory, a PRAM, an MRAM, a ReRAM, or a FRAM. For example, the storage device 2300 may include a storage medium such as a solid state drive (SSD), an embedded multimedia card (eMMC), or a universal flash storage (UFS). The controller may control the memory device such that the memory device stores or outputs data.

The communication block 2400 may communicate with an external device/system of the electronic system 2000. For example, the communication block 2400 may support at least one of various wireless communication protocols such as long term evolution (LTE), worldwide interoperability for microwave access (WiMax), global system for mobile communication (GSM), code division multiple access (CDMA), Bluetooth, near field communication (NFC), and wireless fidelity (Wi-Fi), radio frequency identification (RFID) and/or at least one of various wired communication protocols such as transfer control protocol/Internet protocol (TCP/IP), universal serial bus (USB), and Firewire.

The user interface 2500 may perform communication arbitration between a user and the electronic system 2000. For example, the user interface 2500 may include input interfaces such as a keyboard, a mouse, a keypad, a button, a touch panel, a touch screen, a touch pad, a touch ball, a camera, a microphone, a gyroscope sensor, and a vibration sensor. For example, the user interface 2500 may include output interfaces such as a liquid crystal display (LCD) device, a light emitting diode (LED) display device, an organic LED (OLED) display device, an active matrix OLED (AMOLED) display device, a speaker, and a motor.

A bus 2600 may provide a communication path between the components of the electronic system 2000. The components of the electronic system 2000 may exchange data with each other based on the bus format of the bus 2600. For example, the bus format may include at least one or more of various interface protocols such as USB, small computer system interface (SCSI), peripheral component interconnect express (PCIe), mobile PCIe (M-PCIe), advanced technology attachment (ATA), parallel ATA (PATA), serial ATA (SATA), serial attached SCSI (SAS), integrated drive electronics (IDE), enhanced IDE (EIDE), non-volatile memory express (NVMe), and universal flash storage (UFS).

According to an embodiment of the present disclosure, a bitline sensing amplifier which determines data of memory cells by sensing magnitudes of currents of bitlines, comparing the sensed magnitudes, and amplifying a comparison result and a memory device including the same are provided.

While the present disclosure has described the inventive concept with reference to embodiments thereof, it will be apparent to those of ordinary skill in the art that various changes and modifications may be made thereto without departing from the inventive concept. The language of the claims should be referenced in determining the scope of the invention.

What is claimed is:

1. A bitline sensing amplifier configured to read data of a memory cell, the bitline sensing amplifier comprising:
an equalization circuit connected to a first node and a second node, the equalization circuit configured to provide an equalization voltage to the first node and the second node; and
an amplifying circuit configured to amplify a difference between a first voltage level of the second node and a second voltage level of the first node, the amplifying circuit comprising:
a first p-type metal-oxide-semiconductor (PMOS) transistor connected between the second node and a third node, the first PMOS transistor configured to operate in response to the second voltage level;
a second PMOS transistor connected between the first node and the third node, the second PMOS transistor configured to operate in response to the first voltage level;
a first n-type metal-oxide-semiconductor (NMOS) transistor connected between the second node and a fourth node connected to a first bitline of a first memory cell, the first NMOS transistor configured to operate in response to the first voltage level; and
a second NMOS transistor connected between the second node and a fifth node connected to a second bitline of a second memory cell, the second NMOS transistor configured to operate in response to the second voltage level.

2. The bitline sensing amplifier of claim 1, further comprising:
a first read/write circuit connected to the second node and the fifth node;
a second read/write circuit connected to the first node and the fourth node, wherein the first read/write circuit is provided with first read data of the first memory cell through the second node and provides second write data to be written in the second memory cell through the fifth node, and
wherein the second read/write circuit is provided with second read data of the second memory cell through the first node and provides first write data to be written in the first memory cell through the fourth node.

3. The bitline sensing amplifier of claim 1, wherein the equalization circuit includes:
a first transistor connected between the first node and an equalization node to which the equalization voltage is applied, the first transistor configured to operate in response to an equalization signal; and
a second transistor connected between the equalization node and the second node, the second transistor configured to operate in response to the equalization signal.

4. The bitline sensing amplifier of claim 1, wherein the equalization circuit includes:
a first transistor connected between the first node and an equalization node to which the equalization voltage is applied, the first transistor configured to operate in response to an equalization signal; and
a second transistor connected between the first node and the second node, the second transistor configured to operate in response to the equalization signal.

5. The bitline sensing amplifier of claim 2, wherein the first read/write circuit includes:
an input/output circuit configured to receive the first read data and to provide the second write data;
a first transistor connected between the second node and the input/output circuit, the first transistor configured to operate in response to a read enable signal; and
a second transistor connected between the second node and the fifth node, the second transistor configured to operate in response to a write enable signal.

6. The bitline sensing amplifier of claim 2, wherein the first read/write circuit includes:
an input/output circuit configured to receive the first read data and to provide the second write data;
a first transistor connected between the second node and the input/output circuit, the first transistor configured to operate in response to a read enable signal; and
a second transistor connected between the fifth node and the input/output circuit, the second transistor configured to operate in response to a write enable signal.

7. The bitline sensing amplifier of claim 2, wherein the equalization circuit performs a precharge operation of providing the equalization voltage to the first node and the second node,
wherein a voltage level of the fourth node has a value obtained by subtracting a threshold voltage level of the first NMOS transistor from the equalization voltage in response to the precharge operation, and
wherein a voltage level of the fifth node has a value obtained by subtracting a threshold voltage level of the second NMOS transistor from the equalization voltage in response to the precharge operation.

8. The bitline sensing amplifier of claim 7, wherein the third node is connected to a power NMOS transistor, and
wherein the power NMOS transistor is connected to the third node and a power node to which a power supply voltage is applied and is configured to operate in response to a control signal.

9. The bitline sensing amplifier of claim 8, wherein the second memory cell is a reference cell storing reference data, and
wherein, in response to that wordlines of the first memory cell and the second memory cell are activated,
a first current corresponding to first data of the first memory cell flows through the first node and the fourth node, and
a second current corresponding the reference data of the second memory cell flows through the second node and the fifth node, and
wherein, when data 1 is stored in the first memory cell, the first current is larger than the second current.

10. The bitline sensing amplifier of claim 9, wherein the second voltage level decreases in response to the first current,
wherein the first voltage level decreases in response to the second current, and
wherein, when the data 1 is stored in the first memory cell, in response to that the second voltage level decreases to be faster than the first voltage level, the second NMOS transistor is turned off, and the second voltage level is clamped.

11. The bitline sensing amplifier of claim 10, wherein the power NMOS transistor is turned on through the control signal, and
wherein, when the power supply voltage is provided to the third node, the amplifying circuit starts to amplify the difference between the first voltage level and the second voltage level.

12. The bitline sensing amplifier of claim 11, wherein, when the data 1 is stored in the first memory cell, the amplifying circuit amplifies the first voltage level so as to reach the equalization voltage.

13. A bitline sensing amplifier configured to read data of a memory cell, the bitline sensing amplifier comprising:
an equalization circuit connected to a first node and a second node, the equalization circuit configured to provide an equalization voltage to the first node and the second node;
a first amplifying circuit configured to amplify a difference between a first voltage level of the second node and a second voltage level of the first node; and
a second amplifying circuit configured to disconnect the bitline sensing amplifier from a first bitline connected to a first memory cell and a second bitline connected to a second memory cell,
wherein the first amplifying circuit comprises:
a first n-type metal-oxide-semiconductor (NMOS) transistor connected between the first node and a third node, the first NMOS transistor configured to operate in response to the first voltage level; and
a second NMOS transistor connected between the second node and a fourth node, the second NMOS transistor configured to operate in response to the second voltage level, and
wherein the second amplifying circuit comprises:
a third NMOS transistor connected between a fifth node connected to the third node and the first bitline, the third NMOS transistor configured to operate in response to a first control signal; and
a fourth NMOS transistor connected between a sixth node connected to the fourth node and the second bitline, the fourth NMOS transistor configured to operate in response to the first control signal.

14. The bitline sensing amplifier of claim 13, wherein the first amplifying circuit further includes:
a fifth NMOS transistor connected between a power node to which a power supply voltage is applied and a seventh node, the fifth NMOS transistor configured to operate in response to a second control signal;
a first PMOS transistor connected between the second node and the seventh node, the first PMOS transistor configured to operate in response to the second voltage level; and
a second PMOS transistor connected between the first node and the seventh node, the second PMOS transistor configured to operate in response to the first voltage level.

15. The bitline sensing amplifier of claim 14, wherein the second amplifying circuit further includes:
a sixth NMOS transistor connected between a ground node and an eighth node, the sixth NMOS transistor configured to operate in response to the second control signal;
a seventh NMOS transistor connected between the fifth node and the eighth node, the seventh NMOS transistor configured to operate in response to the second control signal; and
an eighth NMOS transistor connected between the sixth node and the eighth node, the eight NMOS transistor configured to operate in response to the second control signal, and
wherein the first control signal and the second control signal are complementary signals.

16. The bitline sensing amplifier of claim 15, further comprising:
a first read/write circuit connected to the second node and the fourth node; and
a second read/write circuit connected to the first node and the third node,
wherein the first read/write circuit is provided with first read data of the first memory cell through the second node and provides second write data to be written in the second memory cell through the fourth node, and
wherein the second read/write circuit is provided with second read data of the second memory cell through the first node and provides first write data to be written in the first memory cell through the third node.

17. The bitline sensing amplifier of claim 15, wherein the equalization circuit includes:
a first transistor connected between the first node and an equalization node to which the equalization voltage is applied, the first transistor configured to operate in response to an equalization signal; and
a second transistor connected between the equalization node and the second node, the second transistor configured to operate in response to the equalization signal.

18. The bitline sensing amplifier of claim 15, wherein the equalization circuit includes:
a first transistor connected between the first node and an equalization node to which the equalization voltage is applied, the first transistor configured to operate in response to an equalization signal; and
a second transistor connected between the first node and the second node, the second transistor configured to operate in response to the equalization signal.

19. The bitline sensing amplifier of claim 15, wherein the first amplifying circuit amplifies the difference between the first voltage level and the second voltage level in response to the second control signal, and
wherein, in response to the first control signal, the second amplifying circuit disconnects the first bitline and the fifth node and disconnects the second bitline and the sixth node.

20. A memory device configured to store data, the memory device comprising:
a memory cell array configured to store the data and including a first memory cell, a second memory cell, and a bitline sensing amplifier; and
an input/output circuit configured to input or receive the data to or from the memory cell array,
wherein the bitline sensing amplifier includes:
an equalization circuit connected to a first node and a second node, the equalization circuit configured to provide an equalization voltage to the first node and the second node; and
an amplifying circuit configured to amplify a difference between a first voltage level of the second node and a second voltage level of the first node, and
wherein the amplifying circuit includes:
a first NMOS transistor connected between the first node and a third node connected to a first bitline of the first memory cell, the first NMOS transistor configured to operate in response to the first voltage level; and
a second NMOS transistor connected between the second node and a fourth node connected to a second bitline of the second memory cell, the second NMOS transistor configured to operate in response to the second voltage level.
